(19) United States
(12) Patent Application Publication
(10) Pub. No.: US 2019/0123251 A1
(43) Pub. Date: Apr. 25, 2019

(54) Light-Emitting Component

(71) Applicant: OSRAM Opto Semiconductors GmbH, Regensburg (DE)

(72) Inventors: Ingo Neudecker, Regensburg (DE); Juergen Moosburger, Lappersdorf (DE); Andreas Ploessl, Regensburg (DE)

(21) Appl. No.: 16/091,082

(22) PCT Filed: Apr. 7, 2017
(86) PCT No.: PCT/EP2017/058368

§ 371 Date: Oct. 3, 2018

(30) Foreign Application Priority Data
Apr. 7, 2016 (DE) 10 2016 106 387.8

(51) Int. Cl. H01L 33/62; H01L 25/075; H01L 33/00

(52) U.S. Cl. CPC H01L 33/62; H01L 25/0753; G06F 3/1446; H01L 2933/0033; H01L 2933/0066; H01L 33/0095

(57) ABSTRACT

A light-emitting arrangement is disclosed. In an embodiment a light-emitting arrangement includes a carrier, an electrical contact pad formed on the carrier, an electrically conductive contact film arranged on the contact pad and a light-emitting component having an electrical terminal on a first side, wherein the component is located with the first side on the contact film, wherein the electrical terminal is connected to the contact film in an electrically conductive manner, and wherein the electrical terminal is connected to the contact pad in an electrically conductive manner by way of the electrically conductive contact film.

This patent application is a national phase filing under section 371 of PCT/EP2017/058368, filed Apr. 7, 2017, which claims the priority of German patent application 10 2016 106 387.8, filed Apr. 7, 2016, each of which is incorporated herein by reference in its entirety.

### TECHNICAL FIELD

The invention relates to a light-emitting component, a video wall and a method for producing a light-emitting component.

### BACKGROUND

The prior art discloses mounting light-emitting components on contact pads of carriers by means of conductive adhesives. By means of conductive adhesives, a mechanical and electrically conductive connection is produced between the component and the contact pad or the carrier.

### SUMMARY OF THE INVENTION

Embodiments provide an improved light-emitting component and an improved method for producing the light-emitting component.

One advantage of the proposed component is that of allowing simple application of the electrically conductive connecting material. This is achieved in that a contact film is used, which contact film provides an electrical connection between an electrical terminal of the component and an electrical contact pad of the carrier. The contact film is able to be processed simply and cleanly. On the one hand, relatively large areas of the carrier are able to be covered by means of the contact film. On the other hand, defined small regions of the carrier or individual electrical contact pads are able to be covered accurately by way of a correspondingly formed contact film. In addition, components may be arranged on the contact film at a small lateral distance from one another.

By way of example, the contact film may be applied only to the electrical contact pad. This therefore allows defined geometric formation of the electrically conductive connection between the light-emitting component and the electrical contact pad by means of the contact film. As a result, it is possible to arrange two electrically conductive components laterally next to one another at a very small lateral distance from one another, and in particular to connect them in an electrically conductive manner to two separate electrical contact pads, without an electrically conductive connection being formed between the two components through the two contact films. The two contact films are each arranged next to one another on a contact pad and do not make contact with one another. In this case, it is possible to achieve lateral distances between the components, which are connected in particular to different electrical contact pads, of up to less than 100 μm, in particular up to less than 50 μm. Tests show that lateral distances between the components of up to 20 μm are possible. In the case of these small lateral distances as well, the components are able to be connected in a conductive manner to separate electrical contact pads, either via a contact film or via two separate contact films. Depending on the embodiment chosen, the components may also be connected in an electrically conductive manner to the same contact pad via one or two separate contact films. A contact film may be formed, for example, in the form of an adhesive film.

By way of example, in the case of carriers without cavities, such as, for example, in the case of video walls, the contact film may be applied flat on the carrier. The contact film may cover large parts of the carrier, in particular the entire carrier. The carrier may have a plurality of contact pads. The contact film may cover individual, several or all of the contact pads of the carrier. The components are then placed, in particular individually, onto the contact film and, if necessary, as far as possible jointly pressed onto the film with a prescribed pressure. The contact film is cured in a subsequent drying process. It is thus possible to produce video walls having components, wherein the components are at a small lateral distance from one another.

Since the contact film also has a defined thickness over a relatively large surface area, tilting of the components with respect to the contact pad may be avoided. Due to the constant thickness of the contact film, reproducible thermal dissipation of the components is achieved. It is additionally possible to reduce process fluctuations. As a result, the reliability of the connection between the component and the carrier is improved.

Depending on the embodiment chosen, a plurality of components may also be connected in an electrically conductive manner to one or to a plurality of separate contact pads by means of the contact film. To this end, an isotropically conductive contact film may be arranged between the contact pads or the plurality of contact pads.

Furthermore, an anisotropically conductive contact film may be arranged on a plurality of separate contact pads. The respective components with the electrical terminals are applied above the contact pads. The anisotropically conductive contact film ensures that a flow of current takes place only between an upper side and a lower side of the respective contact film, such that an electrically conductive connection is formed only between a contact pad and a first terminal of a component, which terminal is arranged above said contact pad on the contact film. Using the anisotropically conductive contact film, it is thus possible also to produce electrically separate conductive connections between the contact pads and the respective components by means of a single-piece anisotropically conductive contact film. The components are thus able to be electrically driven individually and independently of one another in this embodiment as well. By using an anisotropically conductive contact film, simple construction of the component for producing separate electrical connections to the components is achieved.

In another embodiment, the component has a second electrical terminal, wherein the second electrical terminal is connected to a second electrically conductive contact pad of the carrier via an electrical line, in particular via a bonding wire. The second contact pad of the carrier is at least partially not covered by the contact film.

A good electrical and mechanical connection between the component and the contact film may be achieved if, during the process of curing the contact film, the component is pressed onto the contact film with a prescribed pressure. In the case of the arrangement of a plurality of components on the contact film, it is advantageous if the components are pressed onto the contact film with the same pressure during the curing process. A roughly identical connection is thereby formed between the component and the contact film and the corresponding contact pad of the carrier. In addition, an approximately identical distance is set between the contact pads and the electrical terminals of the components.

In one embodiment, the contact film is applied to the carrier and the contact film is then divided at least into two mechanically separate contact films. A simple and quick method is thus able to be provided in which electrical contact pads of the carrier are connected to components by means of the contact film, wherein at least two groups of electrically isolated contact pads and components are formed. As a result, the electrical terminals of the components may be formed separately. The components are thus able to be electrically driven individually.

### BRIEF DESCRIPTION OF THE DRAWINGS

The above-described properties, features and advantages of this invention, and the manner in which they are achieved, will become clearer and significantly more comprehensible in connection with the following description of the exemplary embodiments, which will be explained in more detail in connection with the drawings. In the figures:

FIG. 1 shows a schematic partial cross section through a component having a contact pad for first electrical terminals of three light-emitting components;

FIG. 2 shows a schematic plan view of the component of FIG. 1;

FIG. 3 shows a schematic partial cross section through another component having an anisotropically conductive contact layer;

FIG. 4 shows a schematic plan view of the component of FIG. 3;

FIG. 5 shows a schematic partial cross section through a component having separate contact films for the individual contact pads of the components;

FIG. 6 shows a schematic plan view of the component of FIG. 5;

FIG. 7 shows a schematic partial cross section through a component having an anisotropic contact film and having three contact pads for the three components;

FIG. 8 shows a schematic plan view of an embodiment of a component having an anisotropic contact film that also covers the second contact pad for the second electrical terminals of the components;

FIG. 9 shows a schematic partial cross section through a component, in which the light-emitting component has two electrical terminals on the lower side and an anisotropically conductive contact film is provided; and

FIG. 10 shows a schematic partial cross section through a component, in which the light-emitting component has two electrical terminals on the lower side and two conductive contact films are provided.

### DETAILED DESCRIPTION OF ILLUSTRATIVE EMBODIMENTS

FIG. 1 shows, in a schematic cross section, a carrier 1 on which electrical contact pads 2, 3 are arranged. The first and the second contact pad 2, 3 are arranged on an upper side of the carrier 1 at a prescribed distance from one another. The first and the second contact pad 2, 3 may have a rectangular, a square or a circular surface area. In the exemplary embodiment illustrated, a contact film 6 is arranged on the carrier 1. The contact film 6 covers the first contact pad 2. The contact film 6 has a recess 18 in the region of the second contact pad 3. The second contact pad 3 is arranged in the region of the recess 18 and is not in contact with the contact film 6. Instead of the recess 18, the contact film may be also formed such that only the region of the carrier 1 in the region of the first contact pad 2 is covered with the contact film 6. The contact film 6 may also extend laterally beyond the first contact pad 2 and cover part of the upper side of the carrier 1, in particular regions of the carrier 1 adjoining the first contact pad 2.

A first group of light-emitting components 7, 8, 9 is arranged above the first contact pad 2. Each of the components 7, 8, 9 is configured as a light-emitting component and has a first electrical terminal 11 on a first side 10. By way of example, the components 7, 8, 9 may be configured as laser diodes or as light-emitting semiconductor diodes, in particular light-emitting diode chips. The components 7, 8, 9 are each arranged with the first side 10 on the first contact film 6. In this case, the first electrical terminal 11 is connected to the contact film 6 in an electrically conductive manner. In this case, the first terminals 11 may lie directly on the first contact film 6. The contact film 6 is connected to the first contact pad 2 in an electrically conductive manner. In this case, the first contact film 6 may lie directly on the first contact pad 2. The contact film 6 in the exemplary embodiment illustrated is configured as an isotropically electrically conductive film that is electrically conductive in all directions. The second contact pad 3 is provided in order to supply a voltage to second electrical terminals 12 of the components 7, 8, 9 by means of electrical lines 13, in particular bonding wires. A multiplicity of first and second contact pads 2, 3 and light-emitting components 7, 8, 9 may be arranged on the carrier 1. Just one component or more than three components may also additionally be arranged on the contact film 6. In this embodiment, the contact film 6 is configured either as isotropically conductive contact films or as anisotropically conductive contact films.

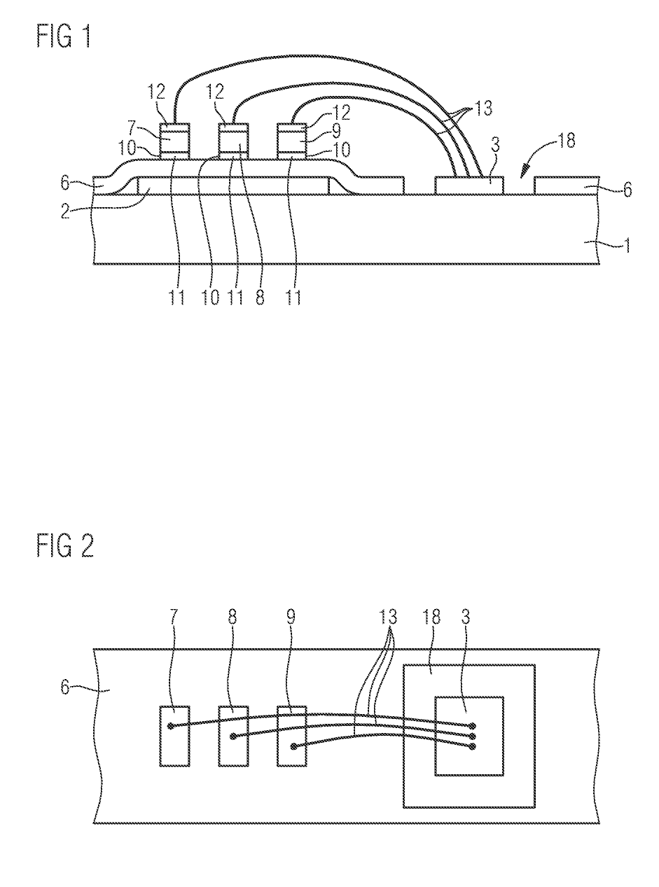

FIG. 2 shows a schematic plan view of the arrangement of FIG. 1, wherein the first, the second and the third component 7, 8, 9 are arranged on the first contact film 6. In addition, the first, second and third component 7, 8, 9 are each connected in an electrically conductive manner to the second contact pad 3 by way of an electrical line 13. Depending on the embodiment chosen, the components 7, 8, 9, by way of the second electrical terminals 12, may also be connected to different second contact pads. The components are thus able to be driven separately.

The electrically conductive connection between the electrical terminals of the components and the contact pads is able to be produced easily in that the contact film is applied to the contact pads. The components, by way of the electrical terminals, are then placed on the contact film 6. There then follows a curing process in which an adhesive connection is produced between the contact film and the electrical terminals of the components and additionally between the contact film 6 and the contact pads. The components may preferably be pressed onto the contact film 6 during the curing process with a prescribed and in particular equal pressure. A secure connection between the components and the contact film is thereby achieved.

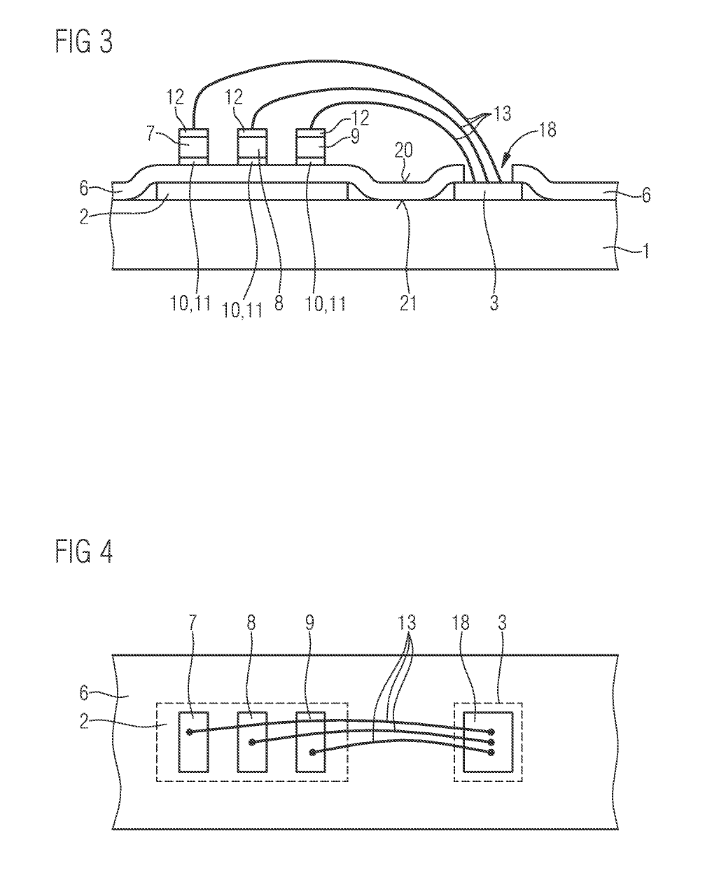

FIG. 3 shows, in a schematic partial cross section through a carrier 1, a further embodiment of a component, wherein a first contact pad 2 and a second contact pad 3 are arranged on the carrier 1. The first and the second contact pad 2, 3 may have a rectangular, a square or a circular surface area. In this embodiment, the contact film 6 is arranged on the first and the second contact pad 2, 3 and above parts of the upper side of the carrier 1. Furthermore, a first, a second and a third component 7, 8, 9 are arranged above the first contact pad 2 on the contact film 6.

Each of the components 7, 8, 9 is configured as a light-emitting component and in each case has a first electrical terminal 11 on a first side 10. By way of example, the components 7, 8, 9 may be configured as laser diodes or as light-emitting semiconductor diodes, in particular light-emitting diode chips. The components 7, 8, 9 are each arranged with the first side 10 on the first contact film 6. In this case, the first electrical terminal 11 is connected to the contact film 6 in an electrically conductive manner. In this case, the first terminals 11 may lie directly on the first contact film 6. The contact film 6 is connected to the first contact pad 2 in an electrically conductive manner. In this case, the first contact film 6 may lie directly on the first contact pad 2. The second contact pad 3 is provided in order to supply a voltage to second electrical terminals 12 of the components 7, 8, 9 by means of electrical lines 13, in particular bonding wires.

The contact film 6 has a recess 18 above the second contact pad 3. The first, second and third component 7, 8, 9 have second electrical terminals 12 that are connected to the second contact pad 3 by way of the electrical lines 13. To this end, the electrical lines 13 are routed to the second contact pad 3 through the recess 18 in the contact film 6.

In this embodiment, the contact film 6 is configured as an anisotropically conductive film that forms an electrical line substantially in a perpendicular direction between an upper side 20 and a lower side 21 of the contact film 6. A current in the lateral direction, that is to say in the direction parallel to the upper side or lower side of the contact film 6, is not possible in the case of the anisotropic contact film 6. The contact film 6 may thus be arranged both on the first contact pad 2 and on the second contact pad 3 without generating an electrical short circuit, even though the two contact pads 2, 3 are routing different electrical potentials. Depending on the embodiment chosen, more or fewer than three light-emitting components may also be provided. In addition, a plurality of first and second contact pads 2, 3, covered by the contact film 6, may also be provided. Furthermore, further light-emitting components may be arranged above the further first contact pad on the contact film and be connected to the contact film by way of first electrical terminals. Furthermore, the further components may have second electrical terminals that are connected to the further second contact pad.

FIG. 4 shows a schematic plan view of the arrangement of FIG. 3. In this case, the first contact pad 2 and the second contact pad 3 are shown only in dashed lines as they are arranged underneath the contact film 6.

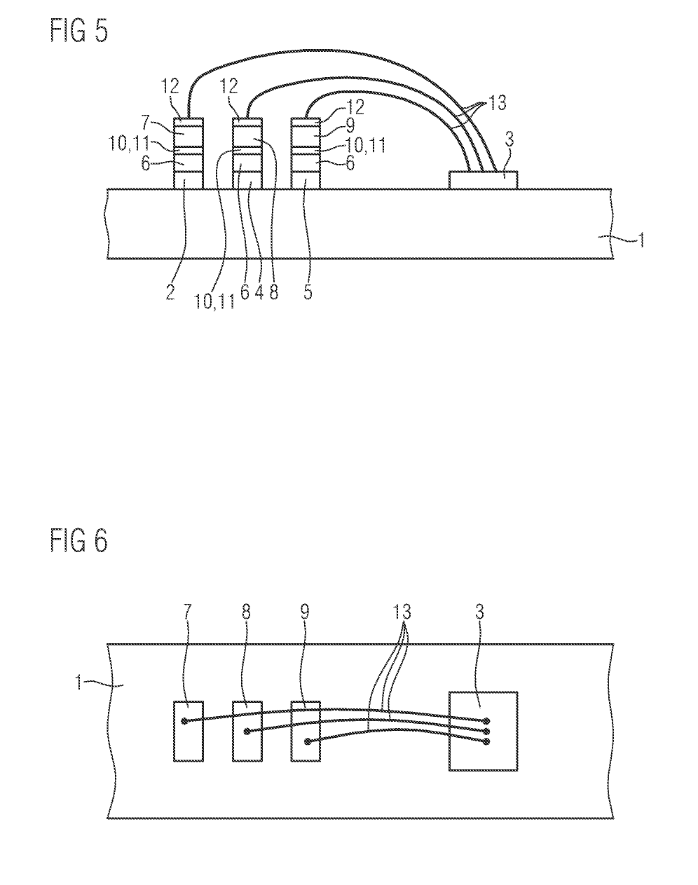

FIG. 5 shows, in a schematic partial cross section through a carrier 1, a further embodiment of a component, wherein a first, a second, a third and a fourth contact pad 2, 3, 4, 5 are arranged on the carrier 1. A contact film 6 is in each case arranged on the first, the third and the fourth contact pad 2, 4, 5. In this embodiment, the contact films 6 have substantially the same surface area as the first, the third and the fourth contact pads 2, 4, 5 on which they are arranged. Depending on the embodiment chosen, the surface area of the contact films 6 may differ from the surface area of the contact pads 2, 4, 5. By way of example, the three contact films 6 may have a larger or a smaller surface area than the respectively associated contact pad 2, 4, 5.

In this embodiment, the first electrical terminals 11 of the components 7, 8, 9 are each separately connected in an electrically conductive manner to the respective contact pad 2, 4, 5 by way of a contact film 6. In this embodiment, the contact films 6 are configured either as isotropically conductive contact films or as anisotropically conductive contact films.

The contact pads 2, 3, 4, 5 may have a rectangular, a square or a circular surface area. Each of the components 7, 8, 9 is configured as a light-emitting component and in each case has the first electrical terminal 11 on a first side 10. By way of example, the components 7, 8, 9 may be configured as laser diodes or as light-emitting semiconductor diodes, in particular light-emitting diode chips. The components 7, 8, 9 are each arranged with the first side 10 on a contact film 6. In this case, the first electrical terminal 11 is connected to the respective contact film 6 in an electrically conductive manner. In this case, the first terminals 11 may lie directly on the associated contact film 6. The contact films 6 are connected to the associated contact pads 2, 4, 5 in an electrically conductive manner. In this case, the contact film 6 may lie directly on the associated contact pad 2, 4, 5. The second contact pad 3 is provided in order to supply a voltage to second electrical terminals 12 of the components 7, 8, 9 by means of electrical lines 13, in particular bonding wires.

Since the components 7, 8, 9 each have a first electrical terminal 11 that is connected to electrically separate electrical contact pads 2, 4, 5, the individual components 7, 8, 9 are able to be electrically driven separately.

FIG. 6 shows a schematic plan view of the arrangement of FIG. 5.

Depending on the embodiment chosen, a multiplicity of groups having a first, second and third component 7, 8, 9 and a first, second, third and fourth contact pad 2, 3, 4, 5 may be arranged on a carrier 1.

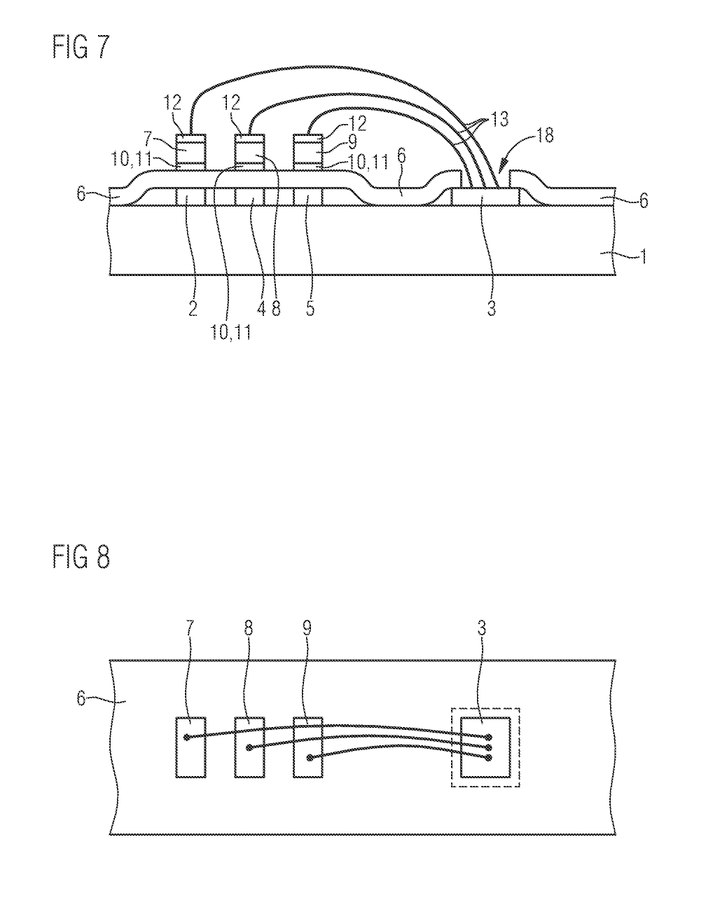

FIG. 7 shows a further arrangement of a component in cross section, formed substantially according to the arrangement of FIG. 5, but with the contact film 6 being arranged continuously on the first, third and fourth contact pad 2, 4, 5. The contact film 6 may additionally also be arranged on the second contact pad 3. The contact film 6 may furthermore have a recess 18 above the second contact pad 3.

The contact pads 2, 3, 4, 5, which are arranged on the carrier 1, may have a rectangular, a square or a circular surface area. Each of the components 7, 8, 9 is configured as a light-emitting component and in each case has the first electrical terminal 11 on a first side 10. By way of example, the components 7, 8, 9 may be configured as laser diodes or as light-emitting semiconductor diodes, in particular light-emitting diode chips. The components 7, 8, 9 are each arranged with the first side 10 on the contact film 6. The first electrical terminals 11 of the components 7, 8, 9 are each arranged directly above a contact pad 2, 4, 5 on the contact film 6.

The first, second and third component 7, 8, 9 have second electrical terminals 12 that are connected to the second contact pad 3 by way of electrical lines 13. To this end, the electrical lines 13 are routed to the second contact pad 3 through the recess 18 in the contact film 6.

In this embodiment, the contact film 6 is configured as an anisotropically conductive film that forms an electrical line substantially in a perpendicular direction between an upper side 20 and a lower side 21 of the contact film 6. A current in the lateral direction, that is to say parallel to the upper side or lower side of the contact film, is not possible in the case of the anisotropic contact film 6. The contact film 6 may thus be arranged both on the first contact pad 2 and on the second contact pad 3 without generating an electrical short circuit, even though the two contact pads 2, 3 are routing different electrical potentials.

The contact film 6 produces an electrically conductive connection between the first terminal 11 of the first component 7 and the first contact pad 2. The contact film 6 produces an electrically conductive connection between the first terminal 11 of the second component 8 and the third contact pad 4. The contact film 6 produces an electrically conductive connection between the first terminal 11 of the third component 9 and the fourth contact pad 5.

Since the components 7, 8, 9 each have a first electrical terminal 11 that is connected to electrically separate electrical contact pads 2, 4, 5, the individual components 7, 8, 9 are able to be electrically driven separately and independently of one another.

Depending on the embodiment chosen, more or fewer than three light-emitting components may also be provided. In addition, a plurality of first and second contact pads 2, 3, covered by the contact film 6, may also be provided. Furthermore, further light-emitting components may be arranged above the further first contact pad on the contact film and be connected to the contact film by way of first electrical terminals. Furthermore, the further components may have second electrical terminals that are connected to the further second contact pad.

FIG. 8 shows, in a schematic arrangement, a plan view of a component, formed substantially in accordance with FIG. 7, with this embodiment however dispensing with the recess 18 and the second contact pad 3 also being covered completely with the contact film 6. The second contact pad 3 is depicted in dashed lines.

The first, third and/or fourth contact pad 2, 4, 5 may, for example, have a negative potential, and the second contact pad 3 may have a positive potential. A reverse potential distribution may also be provided, however.

FIG. 9 shows a schematic partial cross section through a component, in which the light-emitting component 7 has two electrical terminals 11, 12 on the lower side. The component 7 sits, by way of the electrical terminals 11, 12, on a contact film 6. The first electrical terminal 11 is arranged above the first contact pad 2 on the contact film 6, and is connected to the first contact pad 2 of the carrier 1 in an electrically conductive manner by way of the anisotropically conductive contact film 6. The second electrical terminal 12 is arranged above the second contact pad 3, and is connected to the second contact pad 3 of the carrier 1 in an electrically conductive manner by way of the anisotropically conductive contact film 6. The first and the second electrically conductive contact pads 2, 3 are arranged on a carrier 1.

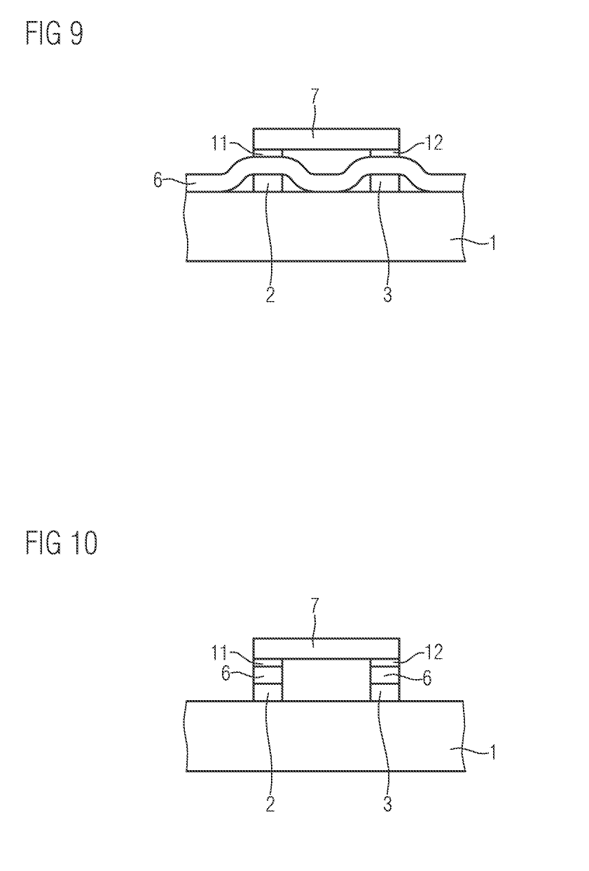

FIG. 10 shows a schematic partial cross section through a component, in which the light-emitting component 7 has two electrical terminals 11, 12 on the lower side. The component 7 sits, by way of the electrical terminals 11, 12, respectively, on a contact film 6. The first electrical terminal 11 is arranged above the first contact pad 2, and is connected to the first contact pad 2 of the carrier 1 in an electrically conductive manner by way of an isotropically or anisotropically conductive contact film 6. The second electrical terminal 12 is arranged above the second contact pad 3, and is connected to the second contact pad 3 of the carrier 1 in an electrically conductive manner by way of a further isotropically or anisotropically conductive contact film 6.

Video walls are, for example, display panels for static or moving images, in which each pixel is formed by one or more light-emitting components, in particular light-emitting diode chips (LED chips). To achieve a high display quality, it is desirable to have small distances between the pixels, a high contrast and equal light emission in different directions in space.

The components described may by way of example be used for a video wall, in which very small lateral distances between the light-emitting components are advantageous. The components may have a multiplicity of light-emitting components that are preferably arranged in a defined pattern with fixed lateral distances from one another. Depending on the embodiment chosen, the individual components may be driven individually or separately in groups. To this end, corresponding cable runs and circuits are provided that are connected to the electrical contact pads 2, 3, 4, 5 of the carrier. By way of example, the light-emitting components 7, 8, 9 may be supplied with current separately from one another by way of the independent and separate driving of the first, third and/or fourth contact pad 2, 4, 5 in the examples described. The cable runs and/or circuits may be integrated in the carrier 1 or formed on the carrier 1.

By means of the embodiments described, it is possible to produce components having light-emitting components in which the components have lateral distances of less than 100 μm, in particular less than 50 μm from one another. The components may be mounted on the contact film at a lateral distance of up to 20 μm and less.

By means of the contact film, it is possible to use a simple method for producing the component. The required contact pads are first of all applied to the carrier. The contact film is then applied to the carrier and to at least one part, in particular to all of the contact pads. The light-emitting components are then arranged on the contact film. In a subsequent curing step, the components are preferably pressed onto the contact film with a prescribed pressure. The components have, on the lower side, a first electrical terminal that is connected to the underlying contact pad in an electrically conductive manner by means of the contact film. Additionally, a mechanical connection is achieved between the component and the contact pad or the carrier by means of the contact film. The contact film may be used in particular in cavity-free carriers.

The contact film is an electrically conductive film that is applied to the carrier having the contact pads at an elevated temperature of 65° C., for example. Corresponding contact films (die attach film) are marketed, for example, by Henkel under the product name LOCTITE ABLESTIK CDF 200PCDF. The contact film may have a relatively large surface area in order to cover entire wafers, or else a small surface area of 0.2×0.2 mm. The contact film may additionally have a thickness of 50 μm. The contact film is produced from an adhesive and electrically conductive material that forms an adhesive and electrically conductive connection between the components and the contact pads or the carrier after curing.

Although the invention has been further illustrated and described in detail by way of the preferred exemplary embodiment, the invention is not limited by the examples disclosed, and other variations may be derived herefrom by a person skilled in the art without departing from the scope of protection of the invention.

1-16. (canceled)

17. A light-emitting arrangement comprising:
a carrier;
an electrical contact pad formed on the carrier;
an electrically conductive contact film arranged on the contact pad; and
a light-emitting component having an electrical terminal on a first side,
wherein the component is located with the first side on the contact film,
wherein the electrical terminal is connected to the contact film in an electrically conductive manner, and
wherein the electrical terminal is connected to the contact pad in an electrically conductive manner by way of the electrically conductive contact film.

18. The arrangement as claimed in claim 17, wherein the carrier has at least one further electrical contact pad, wherein a further contact film is arranged on the further contact pad, wherein a second light-emitting component is arranged with a first side on the further contact film, wherein the second component has an electrical terminal on the first side, and wherein the electrical terminal of the second component is connected to the further contact pad in an electrically conductive manner by way of the further electrically conductive contact film.

19. The arrangement as claimed in claim 18, wherein the two components have a lateral distance from one another that is less than 100 μm.

20. The arrangement as claimed in claim 17, wherein the carrier has at least one further electrical contact pad, wherein the contact film is arranged on the further contact pad, wherein a second light-emitting component is arranged with a first side on the contact film, wherein the second component has an electrical terminal on the first side, and wherein the electrical terminal of the second component is connected to the further contact pad in an electrically conductive manner by way of the contact film.

21. The arrangement as claimed in claim 17, wherein the contact film and/or the further contact film are configured as an isotropically conductive contact film that is configured to be electrically conductive in all directions.

22. The arrangement as claimed in claim 17, wherein the contact film and/or the further contact film are configured as an anisotropically conductive contact film, and wherein the anisotropically conductive contact film is configured to be electrically conductive in a predefined direction between an upper side and a lower side of the contact film, such that an electrically conductive connection is formed only between a contact pad and a first terminal of a component, which terminal is arranged above the contact pad on the contact film.

23. The arrangement as claimed in claim 17, wherein the component has a second electrical terminal, and wherein the second terminal is connected to a second electrically conductive contact pad of the carrier by way of an electrical line.

24. The arrangement as claimed in claim 23, wherein the contact film covers at least part of one side of the carrier, wherein the contact film has a recess, wherein the second contact pad of the carrier is at least partly arranged in the recess, and wherein the electrical line is routed through the recess to the second contact pad.

25. The arrangement as claimed in claim 17, wherein the component has a second electrical terminal, wherein the second terminal is connected to a second electrically conductive contact pad of the carrier by way of an electrical line, wherein the contact film covers at least part of one side of the carrier, wherein the contact film has a recess, wherein the second contact pad of the carrier is at least partly arranged in the recess, wherein the electrical line is routed through the recess to the second contact pad, wherein the component has a second electrical terminal on the first side, wherein the contact film is arranged on a second contact pad of the carrier, wherein the second terminal is arranged on the contact film above the second contact and is connected to the contact film, and wherein an electrically conductive connection is formed between the second terminal and the second contact pad by way of the anisotropically conductive contact film.

26. The component as claimed in claim 17, wherein the carrier has at least one further electrical contact pad, wherein a further contact film is arranged on the further contact pad, wherein a second light-emitting component is arranged with a first side on the further contact film, wherein the second component has an electrical terminal on the first side, and wherein the electrical terminal of the second component is connected to the further contact pad in an electrically conductive manner by way of the further electrically conductive contact film, wherein at least the one component has a second electrical terminal, wherein the second terminal is connected to a second electrically conductive contact pad of the carrier by way of an electrical line, wherein the contact film covers at least part of one side of the carrier, wherein the contact film has a recess, wherein the second contact pad of the carrier is at least partly arranged in the recess, and wherein the electrical line is routed through the recess to the second contact pad.

27. A video wall comprising:
at least one arrangement according to claim 17,
wherein the arrangement has at least two light-emitting components, and
wherein the components have a lateral distance from one another that is less than 100 μm.

28. A method for producing the light-emitting arrangement as claimed in claim 17, the method comprising:
providing a carrier having at least one electrical contact pad;
applying an electrically conductive contact film to the at least one contact pad;
providing a light-emitting component having an electrical terminal on a first side; and
placing the component with the first side on the contact film,
wherein at least one contact is produced between the electrical terminal and the contact film, and wherein an electrically conductive connection is produced between the contact film and the electrical terminal and between the contact film and the contact pad.

29. The method as claimed in claim 28, further comprising pressing the component with the first side on the contact film with a prescribed pressure.

30. The method as claimed in claim 28, further comprising curing the contact film for a prescribed time in order to form an adhesive connection for the electrical terminal and the contact pad.

31. The method as claimed in claim 28, wherein the contact film is applied to the carrier, wherein the contact film lies on at least two contact pads of the carrier, and wherein two light-emitting components having electrical terminals on first sides are provided, wherein the two components are placed with the first sides on the contact film above a respective contact pad, and wherein an electrically conductive connection is produced between the electrical terminals of the two components, the contact film and the respective contact pad.

32. The method as claimed in claim 31, wherein the contact film is interrupted between the two contact pads such that two separate contact films are obtained, wherein a first contact film is located on a first contact pad, and wherein a second contact film is located on the further contact pad.

33. The method as claimed in claim 31, wherein the contact film is configured as an electrically isotropically conductive film, and wherein the contact film only produces an electrically conductive connection between the electrical terminal of a component and the contact pad arranged underneath the first electrical terminal.
